(19) United States
(12) Patent Application Publication
(10) Pub. No.: US 2002/0102800 A1
(43) Pub. Date: Aug. 1, 2002

(54) Method for the manufacture of a semiconductor device with a field-effect transistor

(76) Inventor: Renerus Antonius Van Den Heuvel, Nijmegen (NL)

Correspondence Address: Michael E. Marion, U.S. Philips Corporation, 580 White Plains Road, Tarrytown, NY, 10591, US

(21) Appl. No.: 10/014,243

(22) Filed: Dec. 11, 2001

(30) Foreign Application Priority Data
Dec. 11, 2000 (EP) 00204429.5

(51) Int. Cl. H01L 21/336

(52) U.S. Cl. 438/301; 438/287; 438/303; 438/306

(57) ABSTRACT

The invention relates to the manufacture of a so-called LDMOSFET, in which a gate oxide (1) layer is not only deposited under the gate electrode (1) but also on both sides thereof. Against the sides of the gate electrode (1), which comprises silicon nitride, spacers (5) are positioned, which comprise a material that is selectively removable from the material of the gate oxide layer (1). The drain (3) is provided with a lightly doped part (3A) bordering the gate electrode (1).

According to the invention the lightly doped part (3A) of the drain (3) is formed by means of two additional masking layers (6,7) and the drain (3) is positioned at a distance from the gate electrode (1) which is larger than the width of the spacers (5). Preferably, the spacers (5) are used for silicidation of the gate electrode (1). In this way the method results in a particularly simple manner in a discrete LDSMOST that is highly suitable for application in a base station of a mobile telephone system wherein a high operating voltage and a high frequency are requested. Preferably, a shielding electrode (27) is positioned over the gate electrode (1).

Method for the manufacture of a semiconductor device with a field-effect transistor The invention relates to a method for the manufacture of a semiconductor device with a field-effect transistor with a gate electrode, a source region and a drain region, wherein a gate oxide layer is formed on a surface of a semiconductor body of silicon, on which gate oxide layer the gate electrode containing a polycrystalline silicon layer is provided locally, wherein the source and the drain region are formed, in the semiconductor body, on both sides of the gate electrode and part of the drain region bordering the gate electrode is provided with a low doping concentration, and wherein a spacer of a material that can be selectively etched with respect to the gate oxide layer is produced on both sides of the gate electrode. Such a method is particularly suitable for the manufacture of a so-called LDMOSFET (=Laterally Diffused Metal Oxide Semiconductor Field Effect Transistor) which is highly suitable for many applications. Thanks to the presence of the lowly doped part of the drain region, the generation of hot charge carriers due to a high electrical field is limited near the edges of the gate electrode, which is beneficial to the life and reliability of the transistor.

A similar method is known from American patent U.S. Pat. No. 5,424,234, which was published on Jun. 13, 1995. It describes a method in which a gate oxide layer with a gate electrode on it is formed on the surface of a silicon semiconductor body. A spacer is provided on both sides of the gate electrode, by means of which the drain region (and also the source region) is provided with a lowly doped part bordering the gate electrode. The spacer of this LDDMOST (=Lowly Doped Drain MOST) is built up of two parts that are used as masks for the purpose of building up also the lowly doped part of the drain of two parts.

A drawback of the known method is that it is less suitable for the manufacture of a LDMOSFET that is used, for instance as an amplifier, in a base station for mobile communication. In this application the LDMOSFET must operate at a relatively high operating voltage up to 25 volts and at high frequencies up to approximately 2 GHz.

Consequently, it is an object of the present invention to provide a method by means of which a LDMOSFET is obtained that is eminently suitable for the said application and, hence, functions perfectly at relatively high voltages and high frequencies. Besides, the method should be as simple and inexpensive as possible.

To achieve this, according to the invention a method of the type mentioned in the introduction is characterised in that for the formation of the drain region and the lowly doped part thereof two additional masking layers are produced on the surface of the semiconductor body, the drain region being formed at a distance from the gate electrode that is larger than the width of the spacer. The invention is based on the surprising insight that with no more than two additional masking layers both the drain region and a lowly doped part thereof can be produced in a simple manner, the latter part being (much) longer than when its length is determined by the width of the spacer. Thus, using a method according to the invention a device has been manufactured that is suitable for use at a high voltage. In addition, the presence of a spacer offers a very useful possibility for application also on the side of the drain region, namely depositing a silicide layer on the gate electrode as well as on the source and drain region. As a result the resistance of particularly the gate electrode can be decreased considerably, which is essential when the dimensions of the gate electrode are reduced with a view to operation at higher frequencies. Thanks to a method according to the invention, particularly this silicidation is possible without the lowly doped extension of the drain being silicidised as well. This is very much desired for a satisfactory operation of a device thus manufactured. The above is possible particularly because on the one hand the gate oxide layer is present also outside the gate electrode and on the other hand because this layer outside the gate electrode is saved, among other things owing to the fact that the spacers contain a material that is selectively removable with respect to the material of the gate oxide layer. Thus, in a very simple manner, using a method according to the invention a LDMOSFET is obtained that is particularly suited for the intended application in a base station for mobile telephony.

In a very important embodiment of a method according to the invention, with a view to the formation of the lowly doped part of the drain region on the side of the gate electrode of the source region to be formed on the surface of the semiconductor body, a first masking layer is deposited that extends so far as to be on the gate electrode, and for the formation of the drain region a second masking layer is deposited on the surface of the semiconductor body that extends from the gate electrode up to the drain region to be formed. Preferably, photoresist layers are chosen for the masking layers. Ion implantation is the most suitable technique for the formation of the drain region and the lowly doped part thereof. Preferably, during these implantations a separate protective layer is deposited on the upper side of the gate electrode, so that the material of the gate electrode and that of the region of the device lying underneath the gate electrode—as far as it is not covered by a photoresist layer—is protected from this.

Preferably, first an additional implantation is performed for the formation of a channel region. After that, using the first additional masking layer, the implantation is carried out to form the lowly doped part of the drain region. After removal of the masking layer(s) in question, the repair of the crystal damage caused by both implantations can take place immediately after each implantation, but is preferably carried out in combination. This has the advantage that the regions in question can be accurately positioned under the gate electrode. Next, using the other additional masking layer, an implantation is carried out in which the source and drain regions of the transistor are formed, after which a tempering step is performed. Preferably, the additional masking layers are so dimensioned that the drain region is at a distance of 1 to 4 μm from the gate electrode, a distance which then corresponds to the length of the lowly doped part of the drain region. As a result, operation of a manufactured device is possible at a substantially higher voltage than when the said length corresponds to the width of a spacer which, in practice, cannot be larger than a few tenths of a micrometer.

In a preferred embodiment of a method according to the invention apertures are made in the gate oxide layer at the location of the source and drain regions, and at the location of the apertures, a metal layer by means of which a silicide is formed with the aid of the underlying silicon is deposited on the gate electrode and the source and drain regions. A titanium layer for instance may be chosen for the metal layer, but layers of tungsten, cobalt or platinum are suitable alternatives. After silicide formation has taken place as a result of a suitable heat treatment, the non-converted parts of the titanium layer can simply be removed by etching.

In a very favourable variant of a method according to the invention, an isolating layer is deposited on the gate electrode, after which at the location of the gate electrode a shielding electrode is produced on this layer. For a satisfactory power gain of the LDMOSFET the capacitance between the gate electrode and the drain region should be kept as low as possible. Up till now this is realised by providing a so-called shielding electrode on an isolating layer between the gate electrode and the drain region, the shielding electrode being short-circuited externally to the source region, in the present case to earth. Thanks to silicidation of the gate electrode instead of metallisation, as is usual in the manufacture of a discrete LDMOSFET, it is possible to provide this shielding electrode (also) over the gate electrode instead of between the gate electrode and the drain region. This shielding electrode can be short-circuited to the adjacent source region over the full length of the gate electrode. Thus, a much better shielding is achieved and hence a very good power gain.

The spacers can be formed advantageously by the deposition of a silicon nitride layer on the gate electrode that is subsequently removed by means of plasma etching, the spacers present on both sides of the gate being saved. Preferably, the spacers are formed in a similar way from a double layer of silicon nitride and polycrystalline silicon. The polysilicon parts of the spacers formed after etching of the polycrystalline silicon layer then serve as masks for the etching of the underlying nitride layer with phosphoric acid. In this way L-shaped spacers are formed against the gate electrode. The polysilicon parts can then be removed by etching with potassium hydroxide. This method has several advantages. The main advantage is that the gate oxide layer on both sides of the gate electrode is then saved, which is essential for a selective silicidation. If desired, the spacer could be used also to provide the lowly doped part of the drain region with two sub-parts of different doping concentrations.

Although a method according to the invention is highly suitable for making a discrete LDMOSFET, also other components such as semiconductor elements, but particularly passive components, can be advantageously integrated into the semiconductor body of the LDMOSFET, resulting in a so-called MMIC (=Monolithic Microwave Integrated Circuit).

These and other aspects of the invention are apparent from and will be elucidated, by way of non-limiting example, with reference to the embodiment(s) described hereinafter.

In the drawings:

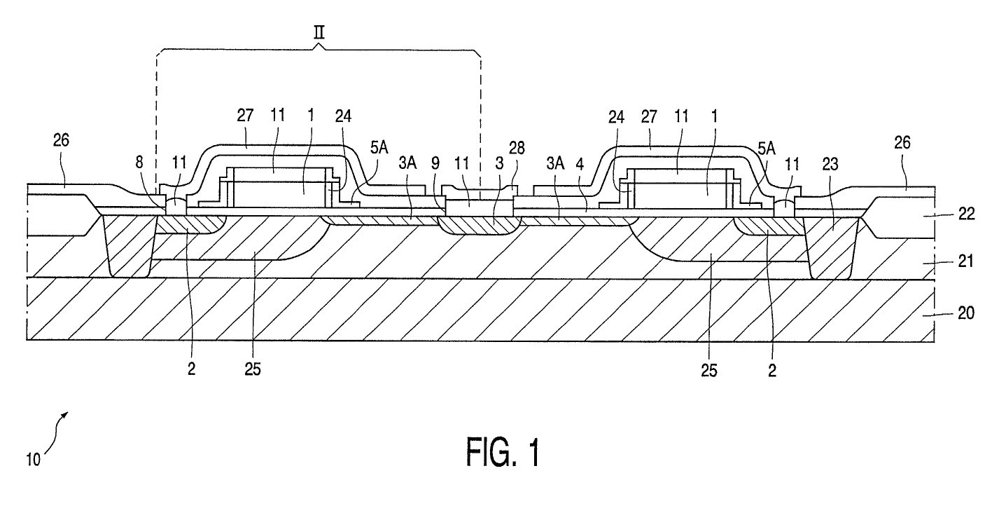

FIG. 1 shows schematically and in a cross section perpendicular to the thickness direction a semiconductor device with a LDMOS transistor manufactured by means of a method according to the invention, and

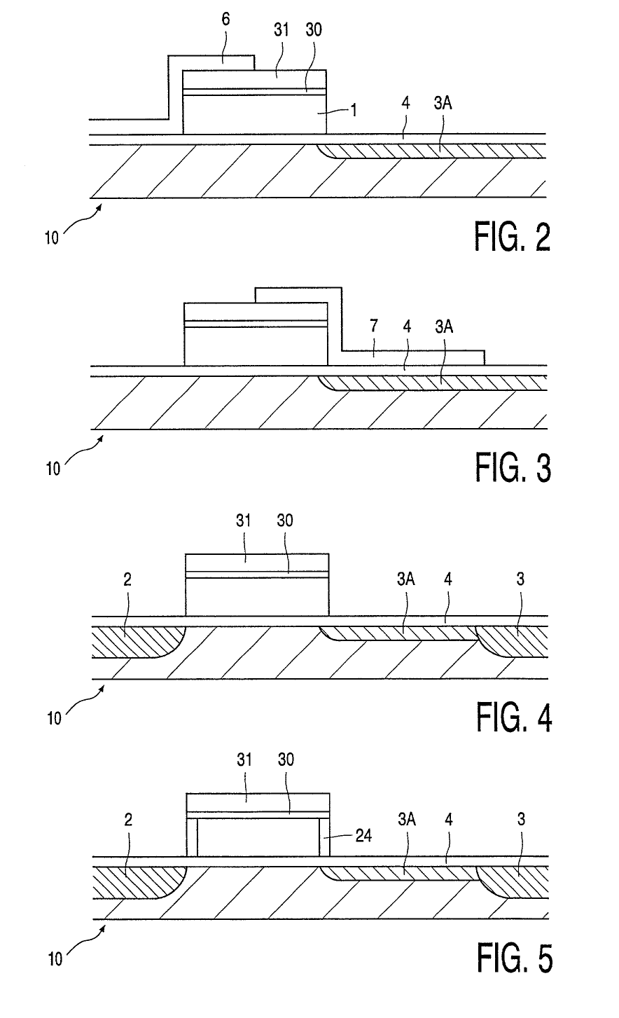

FIGS. 2 to 9 show schematically and in a cross section perpendicular to the thickness direction the part of the semiconductor device marked II in FIG. 1 in successive stages of the manufacture by means of an exemplary embodiment of a method according to the invention.

The figures have not been drawn to scale and particularly the dimensions in the thickness direction are exaggerated strongly for the sake of clarity. Where possible, corresponding regions have been marked with the same reference number and regions with the same conductivity type have, where possible, been given the same hatching.

FIG. 1 shows schematically and in a cross section perpendicular to the thickness direction a semiconductor device with a LDMOS transistor manufactured by means of a method according to the invention. The device comprises a semiconductor body 10 with a p-type silicon substrate 20 provided with a p-type epitaxial layer 21, having a thickness of 100 to 500 μm and 4 to 10 μm respectively and a resistivity of 5 to 1000 mΩcm and 5 to 30 Ωcm respectively. The LDMOSFET is surrounded by LOCOS (=Local Oxidation of Silicon) regions 22. Located on both sides of the n-type drain region 3, which has been provided with lowly doped parts 3A, is the gate electrode 1 that is surrounded by n-type source region 2. In addition, the semiconductor body 10 contains a p-type plug region 23, which provides an electrical connection for the substrate 20 and a p-type channel region 24 by means of which the conductivity properties of the LDMOSFET have been adjusted. The gate electrode 1, which is approximately 1 μm wide here, comprises a polycrystalline silicon layer I that is doped with P atoms and is positioned on a 50 to 90 nm thick gate oxide layer 4 of silicon dioxide, which extends over the surface of the semiconductor body 10 on both sides of the gate electrode 1. The latter is further provided with a lateral layer 25 which contains silicon dioxide and against which spacers 5A of silicon nitride are positioned. Located on the upper side of the gate electrode 1 and in apertures 8,9 in the gate oxide layer 4 situated over the source region 2 and the drain region 3, and in the present case in an isolating layer 26 covering the device, is a conductive layer 11 of titanium silicide. At the location of the gate electrode 1 and the part of the device located between the drain region 3 and the gate electrode 1, there is a shielding electrode 27 on the isolating layer 26. The part marked II of the device already contains the parts that are essential to the present invention, and the manufacture of the device by means of a method according to the invention will be discussed with reference to that part of FIG. 1.

FIGS. 2 to 9 show schematically and in a cross section perpendicular to the thickness direction the part of the semiconductor device marked II in FIG. 1 in successive stages of the manufacture, using an exemplary embodiment of a method according to the invention. Taken as a basis (see FIG. 2) is a p-type silicon substrate 20 that is covered with a p-type epitaxial layer 21. The surface of the semiconductor body 10 is then provided with a LOCOS region 22, within which a gate oxide layer 4 is formed. Deposited on it is a 200 to 500 nm thick gate electrode 1 of polycrystalline silicon that is covered with a 5 to 10 nm thick intermediate layer 30 of silicon dioxide and a 100 to 300 nm thick shielding layer 31 of silicon nitride. Next, using the gate electrode 1 and a masking layer that is located on it and to the right thereof and is not shown in the figures, a p-type channel region 25 is formed by implantation of boron ions, in the present case at a flux of 2 to 8 times 10¹³ at/cm² and at an energy of 30 to 90 keV. Then a 1 μm thick first additional masking layer 6 in the form of a photoresist layer 6 is deposited on and to the left of the gate electrode 1. After that, the n-type lowly doped part 3A of the drain region 3 is formed by implantation of P ions. In this example the flux and energy amount to 1 to 6 times 10¹² at/cm² and 10 to 160 keV respectively. Next, after removal of the resist layer 6, the atoms of both the p-type channel region 25 and those of the lowly doped part 3A of the drain region 3 are electrically activated by a heat treatment at 950 to 1100° C. for 20 to 60 minutes. In this process also the crystal damage caused by the implantations is repaired and the said regions 25,3A diffuse up to the desired position under the gate electrode 1.

Then (see FIG. 3) a second additional masking layer 7, in the present case a photoresist layer 7 too, is deposited on the gate electrode 1 and to the right thereof, after which both the source region 2 and the drain region 3 (see FIG. 4) are formed by implantation of As ions at a flux of 2 to 8 times 10¹⁵ at/cm² and at an energy of 100 to 170 keV. Here the drain region 3 is located at a distance of 3 μm from the gate electrode 1. Next, after removal of the resist layer 7, the implanted ions are activated at a temperature of 900° C. for 15 minutes.

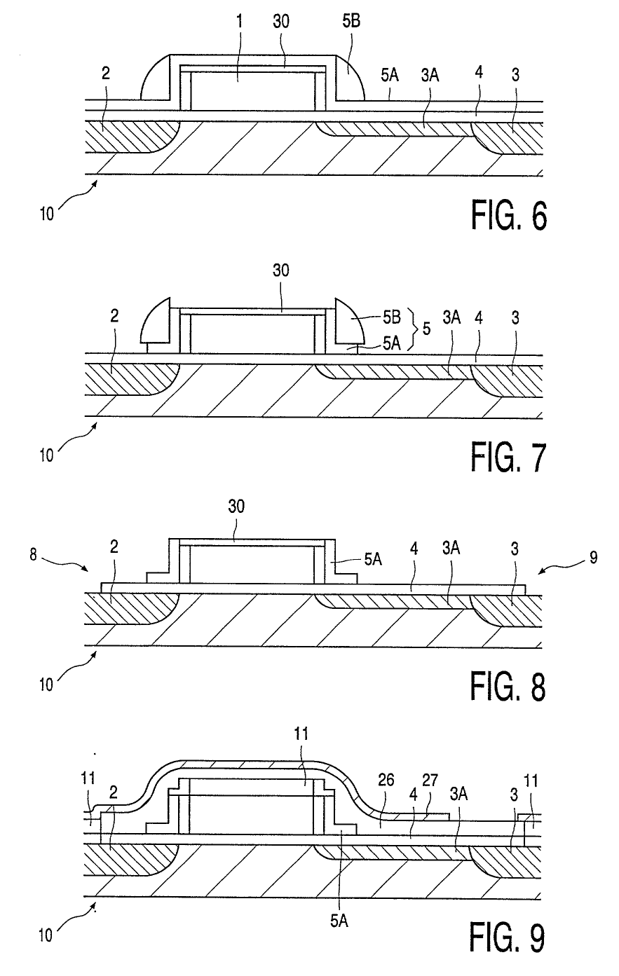

Then (see FIG. 5) the sides of the gate electrode 1 are provided with a lateral oxide layer 24 by a thermal oxidation at 850 to 1000° C. The layer is intended to lower the field under the edge of the gate electrode, which leads to a lesser degradation of the device, and has a thickness of 5 to 20 nm. After that, the nitride shielding layer 31 on the gate electrode 1 is removed by wet chemical etching with phosphoric acid. Then (see FIG. 6) a 30 to 80 nm thick silicon nitride layer 5A and a 200 nm thick polycrystalline silicon layer 5B are deposited on the semiconductor body 10. The latter layer is removed by plasma etching, saving the parts 5B of the spacers 5 to be formed, the silicon nitride layer SA then acting as an etch stop layer. The use of such a double layer 5A,5B for the formation of the spacers 5 has the advantage that the gate oxide layer beside the gate electrode remains intact. Now, using the said parts 5B for masking purposes (see FIG. 7), the excess parts of the silicon nitride layer 5A are removed by wet chemical etching with phosphoric acid, the gate oxide layer 4 then acting as an etch stop layer. Now the spacers 5 are approximately 0.25 μm high and approximately 0.2 μm wide. Then (see FIG. 8) the parts 5B of the spacers 5 are removed in a similar manner by etching with KOH, the remaining parts 5A then forming the spacers 5. After that, the oxide-containing intermediate layer 30 is removed by wet chemical etching. Thanks to a suitable choice of the thickness for this layer 30 and the gate oxide layer 4, the parts of the gate oxide layer 4 lying outside the gate electrode 1 are largely saved.

Then (see FIG. 9), on the surface of the semiconductor body 10 a metal layer 11—in the present case a 20 to 70 nm thick titanium layer 11—is deposited, which as a result of a heat treatment of the device at 650 to 800° C. for approximately 30 seconds reacts at the location of the gate electrode I and at the location of the apertures 8,9 formed in the gate oxide layer 4 with the underlying silicon to form a silicide compound. The parts of the metal layer 11 that have not been able to react with silicon are then removed by means of an etchant that is selective with respect to the metal silicide 11. Next, a glass layer 26 having a thickness of 0.5 to 1.5 μm and containing silicon dioxide is deposited on the surface of the semiconductor body 10. On this layer a 500 to 800 nm thick conductive layer 27 of aluminium or gold is deposited, in a pattern such that a shielding electrode 27 is formed over the gate electrode 1 and between gate electrode 1 and the drain region 3. In addition, connecting conductors 27,28 are formed over the titanium silicide 11 of the source and drain region 2,3. In this example the connecting conductor 27 of source region 2 is connected to the shielding electrode 27 over the gate electrode 3.

After the deposition of a so-called scratch protection layer and after grinding of the substrate 20 to the required thickness the LDMOSFET has been manufactured using a method according to the invention and is ready for separation from the semiconductor body 10, and is then (see also FIG. 1) ready for final assembly.

The invention is not limited to the embodiment given as an example, because to the professional many modifications and variations are possible within the scope of the invention. For example other thicknesses, other (semiconductor) materials or other compositions than those mentioned in the example can be used. Also, all conductivity types used can be simultaneously replaced by the opposite types. The techniques used for the deposition of doped semiconductive, isolating or conductive regions can be replaced by others than those mentioned.

Furthermore, it is stated explicitly that the sequence of the various process steps should not necessarily correspond to that chosen in the example. For example, the formation of the source and drain region and / or the lowly doped part thereof can equally be carried out at a later stage of the manufacture.

1. A method for the manufacture of a semiconductor device containing a field-effect transistor with a gate electrode (1), a source region (2) and a drain region (3), wherein a gate oxide layer (4) is formed on a surface of a semiconductor body (10) of silicon, on which gate oxide layer the gate electrode (1) containing a polycrystalline silicon layer (1) is provided locally, wherein the source region (2) and the drain region (3) are formed, in the semiconductor body (10), on both sides of the gate electrode (1) and a part (3A) of the drain region (3) bordering the gate electrode (1) is provided with a lower doping concentration, and wherein a spacer (5) of a material that can be selectively etched with respect to the gate oxide layer (4), is produced on both sides of the gate electrode (1), characterised in that for the formation of the drain region (3) and the lowly doped part (3A) thereof, two additional mask in layers (6,7) are deposited on the surface of the semiconductor body (10), the drain region (3) being formed at a distance from the gate electrode (1) that is larger than the width of the spacer (5).

2. A method as claimed in claim 1, characterised in that for the formation of the lowly doped part (3A) of the drain region (3) a first masking layer (6) extending so far as to be on the gate electrode (1) is produced on the side of the gate electrode (1) of the source region (2) to be formed on the surface of the semiconductor body (10), and a second masking layer (7) extending from the gate electrode (1) up to the drain region (3) to be formed is produced on the surface of the semiconductor body (10).

3. A method as claimed in claim 1 or 2, characterised in that at the location of the source region (2) and the drain region (3) the gate oxide layer (4) is provided with an aperture (8,9) and that at the location of the aperture (8,9) the gate electrode (1) and the source region (2) and the drain region (3) are provided with a metal layer (11), which with the aid of the underlying silicon is converted into a silicide layer (11).

4. A method as claimed in claim 1, 2 or 3, characterised in that the distance from the drain region (3) to the gate electrode (1) is chosen between 1 and 4 μm.

5. A method as claimed in anyone of the above claims, characterised in that on the gate electrode (1) an isolating layer (26) is deposited, on which a shielding electrode (27) is produced at the location of the gate electrode (1).

6. A method as claimed in anyone of the above claims, characterised in that the spacers (5) are formed of a layer (5A) of silicon nitride.

7. A method as claimed in anyone of the above claims, characterised in that the spacers (5) are formed of a layer of silicon nitride (5A) on which a layer (5B) of polycrystalline silicon is deposited.

8. A method as claimed in anyone of the above claims, characterised in that additional semiconductor elements and preferably one or more passive components are integrated into the semiconductor body (10).

9. A semiconductor device comprising a field-effect transistor obtained by means of a method as claimed in anyone of the above claims.
